(19) United States
(12) Patent Application Publication
(10) Pub. No.: US 2017/0256514 A1
(43) Pub. Date: Sep. 7, 2017

(54) OPTICAL ELECTRONIC DEVICE AND METHOD OF FABRICATION

(71) Applicant: STMicroelectronics (Grenoble 2) SAS, Grenoble (FR)

(72) Inventor: Eric Saugier, Froges (FR)

(73) Assignee: STMicroelectronics (Grenoble 2) SAS, Grenoble (FR)

(21) Appl. No.: 15/238,921

(22) Filed: Aug. 17, 2016

(30) Foreign Application Priority Data
Mar. 2, 2016 (FR) 1651766

(51) Int. Cl. H01L 23/00; H01L 21/82; H01L 31/02; H01L 23/48

(52) U.S. Cl. CPC H01L 24/17; H01L 23/481; H01L 21/82; H01L 24/81; H01L 31/02; H01L 2924/14

(57) ABSTRACT

Electronic devices are collectively fabricated from a main wafer which includes optical elements and a secondary wafer that are mounted one on top of the other to form a combined wafer. A mounting face of the secondary wafer is mated to a front face of the main wafer in such a manner that recesses within the mounting face of the secondary wafer are aligned over the optical elements. The thickness of the secondary wafer reduced until the recesses are opened to form ring structures with openings at the recesses. The combined wafer is diced to form electronic devices. A base wafer of the main wafer and the secondary wafer are made of a same semiconductor material (for example, silicon).

### PRIORITY CLAIM

This application claims priority from French Application for Patent No. 1651766 filed Mar. 2, 2016, the disclosure of which is incorporated herein by reference.

### TECHNICAL FIELD

The present invention relates to the field of electronic devices.

### BACKGROUND

Electronic devices are known that comprise an integrated circuit chip, including, in a front face, an optical sensor, a glass plate mounted on this front face, rear electrical connection elements placed on the back face of the integrated circuit chip and electrical connection through vias connecting the rear electrical connection elements and the optical sensor.

These electronic devices are fabricated in a collective manner and result from the dicing of a final wafer comprising a main wafer including, on sites, chips of the integrated circuits and a glass wafer mounted on the main wafer.

### SUMMARY

According to one embodiment, a method is provided for the fabrication of electronic devices.

This method utilizes: a main wafer having a front face and which comprises a base wafer having optical elements on this upper front face and respectively within sites; and a secondary wafer having, in a mounting face, recesses respectively formed at sites on this secondary wafer, corresponding to the sites on the main wafer.

This method comprises: mounting the main wafer and the secondary wafer one on top of the other, the mounting face of the secondary wafer being mated to the front face of the main wafer in such a manner that the recesses are situated on the side of the main wafer and above the optical elements; reducing the thickness of the secondary wafer, starting from its face opposite to its mounting face, at least until the recesses are opened up, in such a manner that the remaining part of the secondary wafer takes the form of a grid and defines a plurality of through-passages above the optical elements; and dicing through the main wafer and the remaining part, in the form of a grid, of the secondary wafer, along the edges of the sites.

The step for reducing the thickness of the secondary wafer may comprise a mechanical operation for removal by abrasion/polishing and/or an operation for removal by chemical attack.

The step for reducing the thickness of the secondary wafer may comprise a mechanical removal operation not reaching the recesses, followed by a chemical attack operation opening up the recesses.

The method may comprise, after mounting and prior to reducing the thickness of the secondary wafer, processing the main wafer including, on the side of its back face, an operation for reducing the thickness of the base wafer and an operation for installation of electrical connection elements.

The step for processing the main wafer may include the formation of electrical connection vias through the base wafer.

The main wafer may comprise, in the sites, electrical connection networks included in a front layer.

The base wafer and the secondary wafer are composed of the same material.

The base wafer and the secondary wafer may be made of silicon.

An electronic device is also provided which comprises an optical integrated circuit chip having a front face and which comprises a base wafer having, on the side of this front face, an optical element, and a secondary wafer mounted on the front face of the chip, this secondary wafer taking the form of a ring bounding a through-passage above the optical element, the base wafer and the secondary wafer being composed of the same material.

The base wafer and the secondary wafer may be made of silicon.

The electronic device may comprise an electrical connection network included within a layer above the base wafer.

The electronic device may comprise electrical connection vias through the base wafer and electrical connection elements on top of the back face, connected to the vias.

### BRIEF DESCRIPTION OF THE DRAWINGS

An electronic device and a collective fabrication mode will now be described by way of non-limiting exemplary embodiments and are illustrated on the appended drawings in which:

FIG. 1 shows a top view of an electronic device;

FIG. 2 shows a cross section of the electronic device along II-II in FIG. 1;

FIG. 3 shows a cross section of initially separated wafers; and

FIGS. 4 to 7 show cross sections illustrating steps for collective fabrication of electronic devices starting from the initial wafers in FIG. 3.

### DETAILED DESCRIPTION

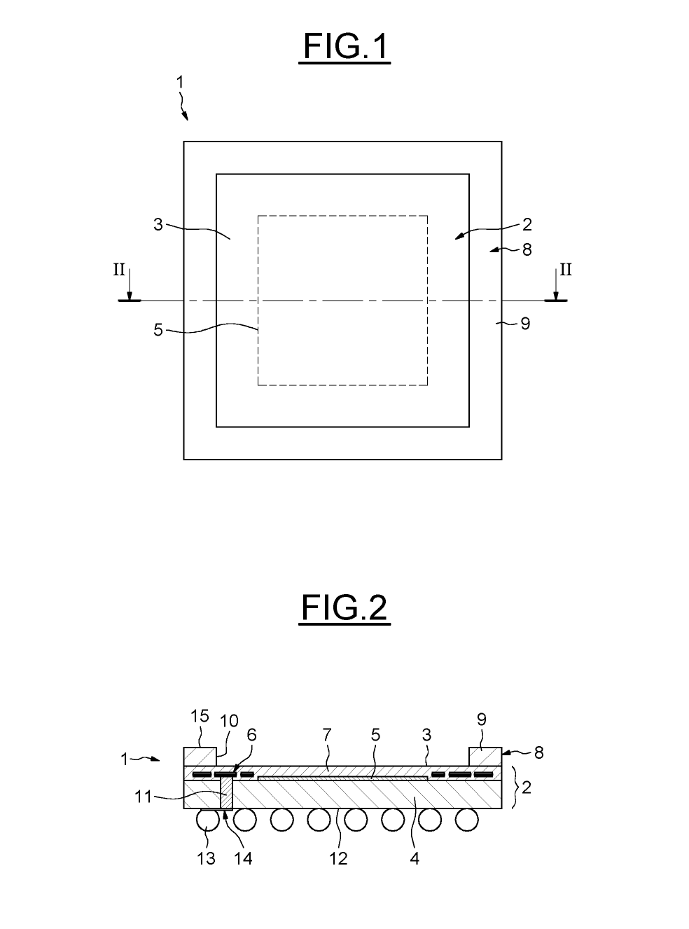

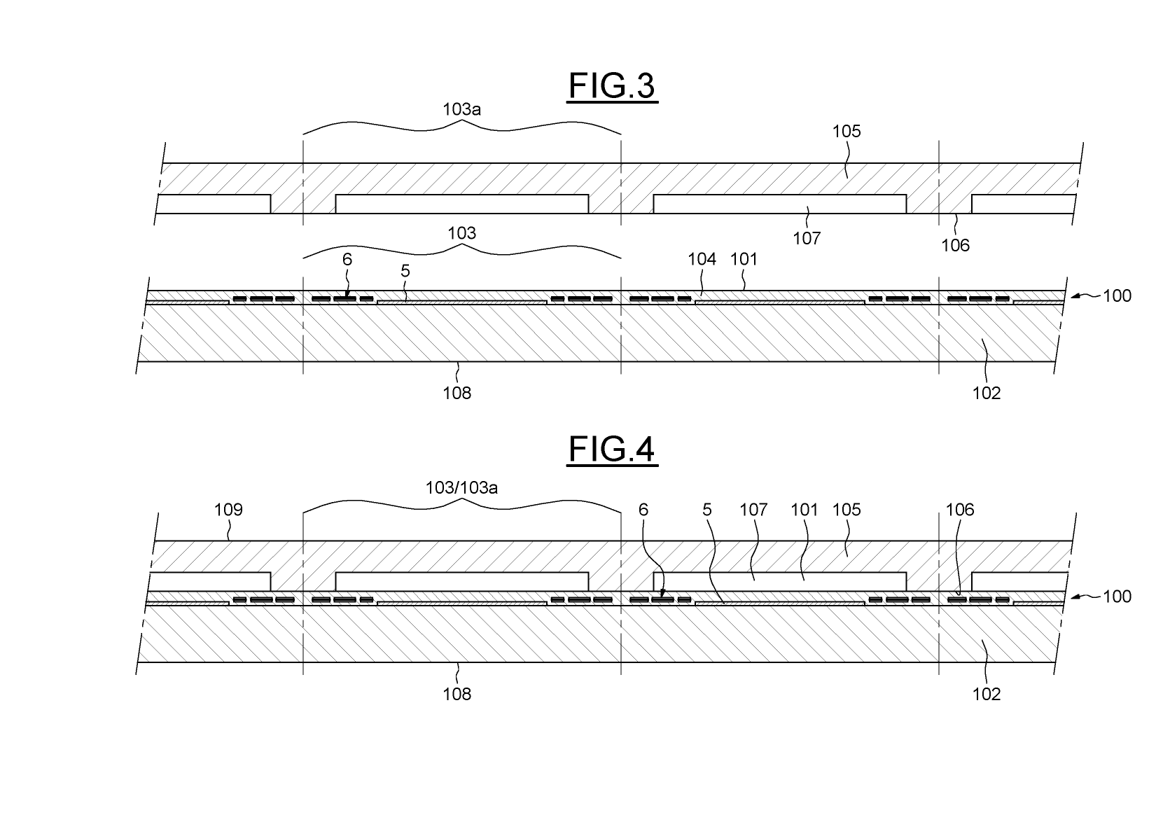

In FIGS. 1 and 2, an electronic device 1 is illustrated which comprises an optical integrated circuit chip 2 having a front face 3 and which comprises a base wafer 4 carrying, on the side of this front face 3, an optical element 5 and an electrical connection network 6 included in a front layer 7 covering the base wafer 4, where this network 6 may comprise several metal levels.

The optical element 5 is provided in a central region of the chip 2 and the electrical connection network 6 is, generally speaking, within the region situated between the outer edge of the optical element 5 and the outer edge of the chip 2.

The optical element 5 may be an optical sensor.

The electronic device 1 further comprises a secondary front wafer 8 mounted on the front face 3 of the chip 2. This secondary wafer 8 takes the form of a front ring 9 (of, for example, square or rectangular shape) which bounds, on its interior, a through-passage 10 extending above the optical element 5. More precisely, the ring 9 is fixed onto the peripheral part of the front face 3 of the chip 2 and surrounds, at a distance, the periphery of the optical element 5.

The chip 2 and the front ring 9 have corresponding contours, such that the electronic device 2 takes the form of a parallelepiped, for example with a square peripheral contour, and the branches (or sides) of the ring 9 have equal widths.

The front ring 9 can be fixed onto the chip 2 by adhesive bonding, for example by means of a polymer adhesive, or by molecular adhesion.

The chip 2 comprises a plurality of electrical connection vias 11 (TSV) formed through the base wafer 4, from the back face 12 of the latter, these vias 11 extending towards the front and being selectively connected to the electrical connection network 6.

The base wafer 4 and the front ring 9 are made of the same material, more particularly of a semiconductor material such as silicon.

The electrical device 1 further comprises a plurality of external electrical connection elements 13, for example metal bump connections, which are installed on top of the back face 12 of the chip 2 and selectively connected to the vias 11 by means of an electrical connection network 14 arranged on top of the back face 12 of the base wafer 4.

The electrical device 1 may be mounted onto a receiving device (not shown), by means of the electrical connection elements 13.

The front ring 9 constitutes a structure for providing reinforcement and mechanical protection for the chip 4. Furthermore, the base wafer 4 and the front ring 9, made of silicon, exhibit identical mechanical behavioral characteristics, more particularly of expansion, such that the chip 4 does not undergo, under the influence of the front ring 9, any bending or torsional forces when the temperature varies.

The front ring 9 forms a bracing element and is able to receive, as a push fit or by adhesive bonding onto its front face 15, an external element (not shown), for example an optical lens.

The electronic device 1 can be produced by a collective fabrication, which will now be described, for the production of a plurality of electronic devices 1.

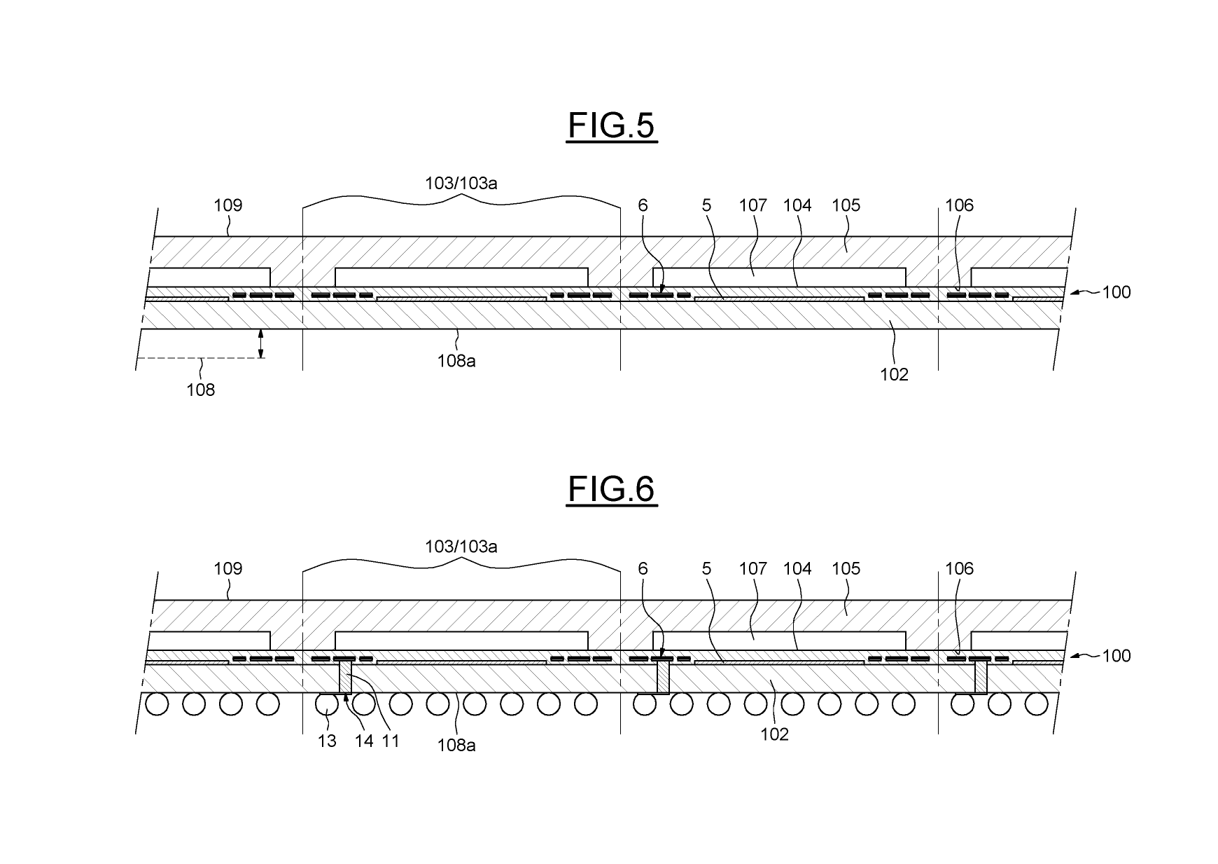

As illustrated in FIG. 3, an initial pre-fabricated main wafer 100 is provided, which has a front face 101 and which comprises a base wafer 102 made of silicon having, on the side of the front face 101 and respectively within each one of a plurality of adjacent sites 103, an optical element 5 and electrical connection network 6 included within a front layer 104.

The adjacent sites 103 are disposed according to a matrix, for example square, corresponding to the contours of electronic devices 1 to be fabricated.

The thickness of the base wafer 102 is greater than the thickness of the base plate 4 of electronic devices 1 to be fabricated.

A secondary initial prefabricated wafer 105 made of silicon is also provided, having, in a mounting face 106, recesses 107 respectively formed within sites 103a on this secondary wafer 105, corresponding to the sites 103 on the main wafer 100.

The recesses 107 have a depth at least equal to the depth of through-passages 10 of electronic devices 1 to be fabricated, in other words at least equal to the thickness of the rings 9 of electronic devices 1 to be fabricated. The recesses 107 have peripheral internal walls corresponding to through-passages 10 of electronic devices 1 to be fabricated.

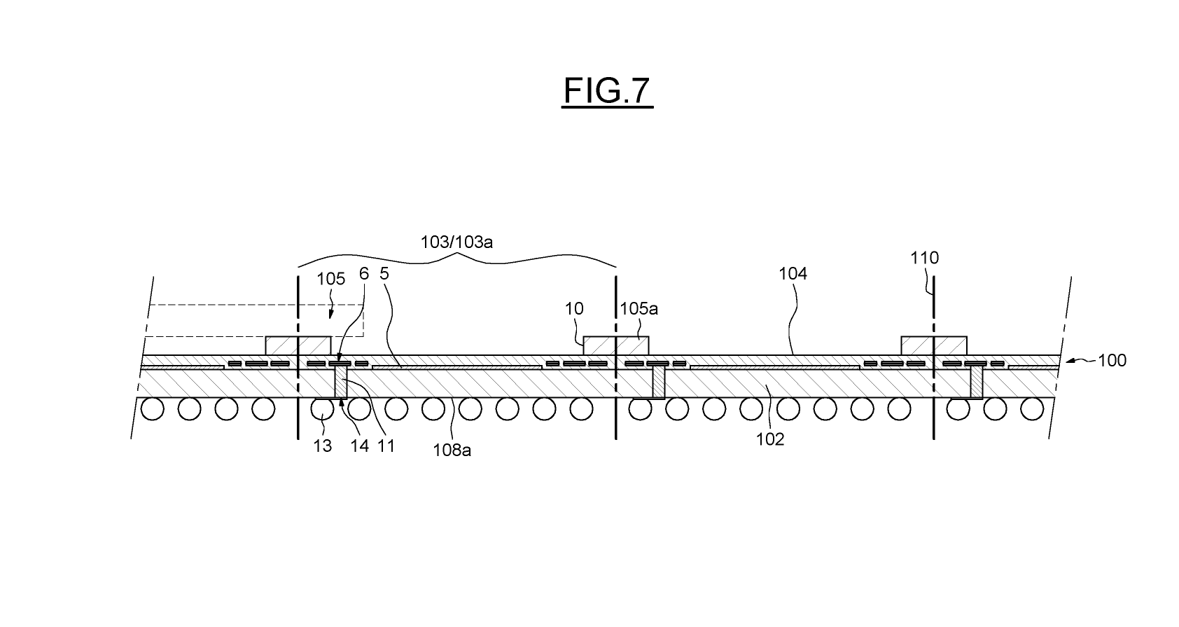

In a mounting step illustrated in FIG. 4, the main wafer 100 and the secondary wafer 105 are mounted one on top of the other, the mounting face 106 of the secondary wafer 105 being mated to the front face 101 of the main wafer 100, in such a manner that the sites 103 and 103a are on top of (i.e., face) one another and that the recesses 107 are situated on the side of the main wafer and above the corresponding optical elements 5.

The mounting face 106 of the secondary wafer 105 may be mated to the front face 101 of the main wafer 100 by molecular adhesion or by adhesive bonding, for example by means of a polymer adhesive, this layer of adhesive not extending over the optical elements.

In a later step illustrated in FIG. 5, a reduction of the thickness of the base wafer 102, starting from its back face 108 and up to the point where the base wafer 102 has a back face 108a. This thickness reduction operation may be carried out by a mechanical abrasion/polishing process and/or by chemical attack.

According to a later step illustrated in FIG. 6, a processing of the main wafer may be carried out.

More particularly, this processing may comprise, respectively in the sites 103, the formation of electrical connection vias 11 through the base wafer 102, starting from the back face 108a, and of electrical connection networks 14 on top of this back face 108a, together with the installation of external electrical connection elements 13, for electronic devices 1 to be fabricated.

In a later step illustrated in FIG. 7, a reduction of the thickness of the secondary wafer 105 is carried out, starting from its front face 109 opposite to its mounting face 106, at least until the recesses 107 are opened up, such that the remaining part 105a of the secondary wafer 105 then takes the form of a grid and defines through-passages 10 which respectively extend over the optical elements 5, for electronic devices 1 to be fabricated. In other words, the branches of the remaining part 105a in the form of a grid, which are rigidly attached to the main wafer 100, extend over the regions of this main wafer 100 that separate the optical elements 5.

This reduction in the thickness of the secondary wafer 105 may be carried out by a mechanical abrasion/polishing process and/or by chemical attack. Optionally, a temporary protection layer could have been deposited on the areas of the front face 101 of the wafer 100 corresponding to the recesses 107 in the wafer 105.

The reduction in the thickness of the secondary wafer may, for example, comprise a mechanical operation for abrasion/polishing until close to the recesses 107, then a chemical attack operation until the recesses 107 are opened up.

After having, where necessary, removed the aforementioned protection layer, a further step consists in carrying out a dicing operation, for example by sawing along the lines and columns 110 of a matrix corresponding to the edges of the superposed sites 103 and 103a, through the main wafer 100 and in the middle of the branches of the remaining part 105a in the form of a grid of the secondary wafer 105.

A plurality of electronic devices 1, such as illustrated in FIGS. 1 and 2, are then obtained.

Owing to the fact that the base wafer 102 and the secondary wafer 105 are made of the same material, i.e. silicon, the sawing operation is facilitated.

According to one variant embodiment, the row and column areas 110 could be clear of adhesive during the operation for bonding the front secondary wafer 105 onto the front face 101 of the main wafer 100.

1. A method for collective fabrication of electronic devices from a main wafer including a plurality of first sites and having a front face and which comprises a base wafer having optical elements on a top surface and located respectively within said first sites, and a secondary wafer including a plurality of second sites and having recesses in a mounting face that are respectively formed within said second sites, wherein said main wafer is a plurality of optical integrated circuit chips and the first sites correspond to the second sites, comprising:
mounting the main wafer and the secondary wafer one on top of the other, with the mounting face of the secondary wafer being mated to the front face of the main wafer in such a manner that the recesses are situated over the optical elements, said main wafer and said secondary wafer being made of a same material;
reducing a thickness of the secondary wafer, starting from a face opposite the mounting face, at least until the recesses are opened, such that a remaining part of the secondary wafer takes the form of a grid and defines a plurality of through-passages extending over the optical elements, wherein the grid is mated to the plurality of optical integrated circuit chips; and
dicing through the main wafer and the remaining part of the secondary wafer along the edges of the first and second sites.

2. The method according to claim 1, wherein reducing the thickness of the secondary wafer comprises a mechanical operation for removal by one or more of abrasion, polishing and chemical attack.

3. The method according to claim 1, wherein reducing the thickness of the secondary wafer comprises:
performing a mechanical removal operation that does not reach the recesses; and
thereafter preforming a chemical attack operation for opening up the recesses.

4. The method according to claim 1, comprising, after the step of mounting and prior to the step of reducing the thickness of the secondary wafer:
reducing a thickness of the base wafer, starting from a face opposite the front face; and
installing electrical connection elements on a back face of a remaining part of the reduced thickness base wafer.

5. The method according to claim 4, further comprising forming electrical connection vias extending through the base wafer from the back face of a remaining part of the reduced thickness base wafer.

6. The method according to claim 1, wherein the main wafer comprises, within each of the first sites, electrical connection networks included in a front layer said front layer forming the front face of the plurality of optical integrated circuit chips to which the grid is mated.

7. (canceled)

8. The method according to claim 1, wherein said same material is a semiconductor material.

9. The method according to claim 8, wherein the semiconductor material is silicon.

10-14. (canceled)

15. A combined wafer, comprising:
a main wafer including a plurality of first sites and having a front face and which comprises a base wafer having optical elements on a top surface and located respectively within said first sites, the main wafer comprising a plurality of optical integrated circuit chips;
a secondary wafer including a plurality of second sites and having recesses in a mounting face that are respectively formed within said second sites, wherein the first sites correspond to the second sites;
wherein said main wafer and said secondary wafer are made of a same semiconductor material; and
wherein said secondary wafer is mounted to the plurality of optical integrated circuit chips with the mounting face of the secondary wafer being mated to the front face of the main wafer in such a manner that the recesses are situated over the optical elements, so as to define a plurality of undiced optical electronic devices arranged in an array.

16. The combined wafer of claim 15, wherein said undiced optical electronic devices are delimited by edges of the first and second sites.

17. The combined wafer of claim 15, wherein a back face of the base wafer opposite said front face of the main wafer is a thinned surface.

18. The combined wafer of claim 17, further comprising:
through vias passing through the base wafer from said back face of the base wafer; and
electrical connection means mounted to said back face of the base wafer and electrically connected to said through vias.

19. The combined wafer of claim 15, wherein a back face of the secondary wafer opposite said mounting face is a thinned surface which defines a grid of ring structures having through openings corresponding to said recesses, the grid of ring structures being mounted to the plurality of optical integrated circuit chips.

20. (canceled)

21. A method, comprising:
forming a plurality of optical integrated circuit chips from a first semiconductor material wafer having optical elements located respectively at first sites;
forming a second semiconductor material wafer including blind opening recesses located respectively at second sites, wherein the first sites correspond to the second sites;
mounting the second semiconductor material wafer to the first semiconductor material wafer with the blind opening recesses facing the optical elements;
reducing a thickness of the second semiconductor material wafer so as to open the blind opening recesses and form a grid with a plurality of through-passages aligned with the optical elements, the grid being mounted to the plurality of optical integrated circuits; and
dicing through the first semiconductor material wafer and a remaining part of the second semiconductor material wafer to produce a plurality of electronic devices.

22. A method, comprising:
providing a main wafer of optical integrated circuits comprising an optical element and an electrical connection network within a front layer, the front layer defining a front face;
providing a secondary wafer having a plurality of blind opening recesses formed in a mounting face;
mounting the mounting face of the secondary wafer to the front face of the main wafer such that each of the plurality of blind opening recesses is disposed above a corresponding optical element;
reducing a thickness of the secondary wafer so as to open the blind opening recesses and form a grid with a plurality of through-passages aligned with the corresponding optical elements; and
dicing through the main wafer and the grid to produce a plurality of individual electronic devices.

23. The method of claim 22 wherein the main wafer and the secondary wafer are formed of a same semiconductor material.

24. The method of claim 23 wherein the mounting face of the secondary wafer is mounted to the front face of the main wafer by one of molecular adhesion and adhesive bonding.
